(19) United States
(12) Patent Application Publication
(10) Pub. No.: US 2026/0312028 A1
(43) Pub. Date: Oct. 8, 2026

(54) CATHODE ACTIVE MATERIAL

(71) Applicant: TOYOTA JIDOSHA KABUSHIKI KAISHA, Toyota-shi (JP)

(72) Inventor: Ryosuke OHSAWA, Okazaki-shi (JP)

(73) Assignee: TOYOTA JIDOSHA KABUSHIKI KAISHA, Toyota-shi (JP)

(21) Appl. No.: 19/463,620

(22) Filed: Jan. 29, 2026

(30) Foreign Application Priority Data
Apr. 2, 2025 (JP) 2025-060880

(51) Int. Cl. H01M 4/525; C01G 53/506; C30B 29/22; C30B 30/04

(52) U.S. Cl. CPC H01M 4/525; C01G 53/506; C30B 29/22; C30B 30/04; C01P 2006/40

(57) ABSTRACT

The cathode active material includes at least one element selected from the group consisting of Ni, Co, and Mn. The cathode active material has a form in which two or more primary particles overlap each other. The primary particles are single crystals having a crystal structure belonging to space group R-3m. The primary particles are stacked such that the (003) planes of the primary particles are oriented parallel to each other. The ratio of the length of the shortest primary particle to the length of the longest primary particle among the primary particles, in a direction parallel to the (003) planes of the primary particles, is from 0.95 to 1.

### CROSS-REFERENCE TO RELATED APPLICATION

This application claims priority to Japanese Patent Application No. 2025-060880 filed on Apr. 2, 2025. The disclosure of the above-identified application, including the specification, drawings, and claims, is incorporated by reference herein in its entirety.

### BACKGROUND

### 1. Technical Field

The present disclosure relates to cathode active materials.

### 2. Description of Related Art

Various techniques have been proposed regarding cathode active materials such as that disclosed in Japanese Unexamined Patent Application Publication No. 2013-65397 (JP 2013-65397 A).

### SUMMARY

Conventionally, various cathode active materials have been proposed in order to obtain a cathode having excellent battery characteristics such as high cycle characteristics and high output characteristics.

In the cathode active material particles disclosed in JP 2013-65397 A, the short-axis faces primary particles correspond to the (003) planes, and secondary particles are formed by the bonding of the short-axis faces to each other. Since the lengths of these short-axis faces are not uniform, the particles exhibit a high specific surface area, which is believed to increase the internal resistance of the battery.

The present disclosure has been made in view of the above, and a primary object thereof is to provide a cathode active material that can reduce the internal resistance of a battery.

The present disclosure includes the following aspects.

(1) A cathode active material including at least one element selected from the group consisting of Ni, Co, and Mn, wherein:
the cathode active material has a form in which two or more primary particles overlap each other;
the primary particles are single crystals having a crystal structure belonging to space group R-3m;
the primary particles are stacked such that (003) planes of the primary particles are oriented parallel to each other; and
the ratio of the length of the shortest primary particle to the length of the longest primary particle among the primary particles, in a direction parallel to the (003) planes of the primary particles, is from 0.95 to 1.

(2) The cathode active material according to (1), wherein:
the cathode active material has a form in which two to ten of the primary particles overlap each other;
the primary particles do not overlap each other in the direction parallel to the (003) planes of the primary particles; and
a short-axis direction of the cathode active material is parallel to the (003) planes of the primary particles.

(3) The cathode active material according to (1) or (2), wherein:
in an outer boundary of the cathode active material observed in a cross-sectional view obtained by a transmission electron microscope, the (003) planes derived from the primary particles are exposed at surfaces extending in the direction parallel to the (003) planes of the primary particles, and planes of the primary particles other than the (003) planes are exposed at surfaces extending in a direction perpendicular to the (003) planes of the primary particles; and
the planes of the primary particles other than the (003) planes are (012) planes, (101) planes, (104) planes, or (110) planes.

(4) A battery including a cathode layer containing the cathode active material according to any one of (1) to (3).

(5) A method for producing the cathode active material according to any one of (1) to (3), the method including:
performing first firing in which a first mixture of a transition metal hydroxide and a lithium compound is fired at 700° C. to 1100° C. to obtain a precursor of the cathode active material;
applying a magnetic field to a slurry in which the precursor of the cathode active material is dispersed in a solvent;
drying the slurry to obtain a dried product;
performing second firing in which the dried product is fired at 800° C. to 1000° C. to obtain a second-fired product; and
cooling the second-fired product at a cooling rate of 0.2° C./min to 0.5° C./min to obtain the cathode active material.

The present disclosure can provide a cathode active material that can reduce the internal resistance of a battery.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic diagram showing an example of the structure of the cathode active material according to the present disclosure.

### DETAILED DESCRIPTION OF EMBODIMENTS

In the present disclosure, an example of a method for calculating an average particle size of particles is as follows. First, in a transmission electron microscope (TEM) image or a scanning electron microscope (SEM) image taken at an appropriate magnification (for example, 50,000× to 1,000,000×), the particle size of a given particle is calculated by treating the particle as a sphere. Such particle size calculations based on TEM or SEM observation are carried out for 200 to 300 particles of the same type, and the average of these particle sizes is taken as the average particle size.

### 1. Cathode Active Material

The present disclosure provides a cathode active material.

The cathode active material includes at least one element selected from the group consisting of Ni, Co, and Mn.
The cathode active material has a form in which two or more primary particles overlap each other.
The primary particles are single crystals having a crystal structure belonging to space group R-3m.
The primary particles are stacked such that (003) planes of the primary particles are oriented parallel to each other.
The ratio of the length of the shortest primary particle to the length of the longest primary particle among the primary particles, in a direction parallel to the (003) planes of the primary particles, is from 0.95 to 1.

In the present disclosure, since the (003) planes, which are the stable planes of the primary particles, are joined together, the specific surface area is reduced and the internal resistance of the battery can be suppressed. In addition, since the stacking of the primary particles is not misaligned, the packing density can be increased, thereby improving the battery capacity.

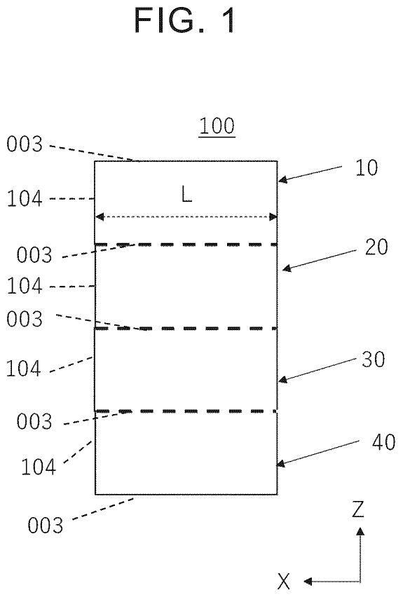

FIG. 1 is a schematic diagram showing an example of the structure of the cathode active material according to the present disclosure. As shown in FIG. 1, a cathode active material 100 of the present disclosure includes a first particle 10, a second particle 20, a third particle 30, and a fourth particle 40 connected in sequence.

The primary particles 10 to 40 are stacked such that their (003) planes are oriented parallel to each other. In other words, the primary particles 10 to 40 do not overlap in a direction parallel to their (003) planes.
In a cross-sectional view of the cathode active material 100, the primary particles 10 to 40 have the same length L in the direction parallel to their (003) planes.
At the outer boundary of the cathode active material 100 observed in cross section, the (003) planes of the primary particles 10 and 40 located at both ends in the stacking direction (Z-direction) are exposed, and other planes of the primary particles 10 to 40, namely the (104) planes, are exposed at surfaces extending in a direction perpendicular to the (003) planes of the primary particles 10 to 40.
When the cathode active material 100 is viewed in cross section, the short-axis direction X of the cathode active material 100 is parallel to the (003) planes of the primary particles 10 to 40.

It is sufficient that the cathode active material contains at least one transition metal (TM) element selected from Ni, Co, and Mn. The cathode active material may be a lithium transition metal composite oxide containing Li, a transition metal, and O. The lithium transition metal composite oxide may contain at least Ni as a transition metal. The lithium transition metal composite oxide may contain two transition metals, three transition metals, or four or more transition metals. Examples of transition metals include Ti, V, Cr, Mn, Fe, Co, Ni, Zr, and Nb.

It is sufficient that the lithium transition metal composite oxide contains at least Ni as a transition metal. The lithium transition metal composite oxide may further contain, for example, Co and Mn as transition metals.
In addition to Li and the transition metals, the lithium transition metal composite oxide may further contain another metal M¹ (including a metalloid) other than Li and the transition metals. Examples of the metal M¹ include Al, Si, Ga, Ge, In, and Sn.
The lithium transition metal composite oxide may contain Li, Ni, Co, Mn, and O.
The total amount of Ni, Co, and Mn contained in the lithium transition metal composite oxide, per 1 mol of all metals contained in the lithium transition metal composite oxide excluding Li, is, for example, 0.80 mol or more, 0.90 mol or more, or 0.95 mol or more, or may be 1 mol. The “total amount of Ni, Co, and Mn” also includes cases where the proportion of one or two of Ni, Co, and Mn is zero.
The lithium transition metal composite oxide may have a composition represented by the general formula LiₓNiₐCo_{b}MnO_{y} (where 0.1≤x≤1.5, 0.5≤a≤1.0, 0≤b≤0.3, 0≤c≤0.3, a+b+c=1.0, and 1.5≤y≤2.1).

In the general formula, the Li composition ratio x may be any value that satisfies 0.1≤x≤1.5. The Li composition ratio x may be, for example, 0.4 or more, 0.6 or more, 0.8 or more, 1.0 or more, or 1.1 or more. The Li composition ratio x may be 1.4 or less, or 1.2 or less. In the above general formula, the O composition ratio y may be any value that satisfies 1.5≤y≤2.1. The O composition ratio y may be, for example, 1.6 or more, 1.7 or more, 1.8 or more, or 1.9 or more. The O composition ratio y may be, for example, 2.0 or less.

In the above general formula, the Ni composition ratio a, the Co composition ratio b, and the Mn composition ratio c satisfy a+b+c=1.0.
In the above general formula, the Ni composition ratio a may be any value that satisfies 0.5≤a≤1.0. The Ni composition ratio a may be, for example, 0.6 or more, 0.7 or more, 0.8 or more, or 0.85 or more. The Ni composition ratio a may be, for example, 0.9 or less.
In the above general formula, the Co composition ratio b may be any value that satisfies 0≤b≤0.3. The Co composition ratio b may be, for example, 0.01 or more, 0.02 or more, 0.03 or more, 0.04 or more, 0.05 or more, 0.06 or more, 0.07 or more, or 0.075 or more. The Co composition ratio b may be, for example, 0.25 or less, 0.20 or less, 0.15 or less, 0.10 or less, 0.09 or less, or 0.08 or less.
In the above general formula, the Mn composition ratio c may be any value that satisfies 0≤c≤0.3. The Mn composition ratio c may be, for example, 0.01 or more, 0.02 or more, 0.03 or more, 0.04 or more, 0.05 or more, 0.06 or more, 0.07 or more, or 0.075 or more. The Mn composition ratio c may be, for example, 0.25 or less, 0.20 or less, 0.15 or less, 0.10 or less, 0.09 or less, or 0.08 or less.

Any dopant may be added to the lithium transition metal composite oxide. The term “dopant” refers to an element other than Li, Ni, Co, Mn, and O. The dopant may include, for example, at least one selected from the group consisting of Zr, Mo, Mg, Ca, Na, Fe, Cr, Zn, Si, Sn, Al, and Ag. The composition ratio d of the dopant, relative to a+b+c=1.0, may be 0.005 or more, 0.01 or more, 0.02 or more, 0.03 or more, or 0.04 or more. The composition ratio d of the dopant, relative to a+b+c=1.0, may be 0.05 or less.

The cathode active material may have a form in which two or more primary particles overlap each other, and may have a form in which n primary particles overlap each other. Here, n may be any integer of 2 or more, and its upper limit may be, for example, 100 or less, 50 or less, 4 or less, or 3 or less.

Each primary particle of the cathode active material is a single crystal having a crystal structure belonging to space group R-3m. In SEM images, a single crystal appears as a single independent particle (primary particle) without apparent agglomeration or aggregation. In SEM images, a single crystal does not exhibit apparent grain boundaries. The magnification for the SEM images may be, for example, from 10,000× to 30,000×.
The crystal structure of the primary particles of the cathode active material may be a layered rock-salt structure.
The cathode active material may also be a polycrystal formed of two or more primary particles. In SEM images, the cathode active material may have one or more grain boundaries, and the upper limit may be, for example, 100 or less, 50 or less, 10 or less, 3 or less, or 2 or less.
The cathode active material may be in the form of particles. The cathode active material particles may be secondary particles in which two or more primary particles overlap each other.
The particle size of the primary particles of the cathode active material may be 0.5 μm or more, 0.6 μm or more, 0.8 μm or more, or 1.0 μm or more. If the particle size of the primary particles is too small, the particles may not have grown sufficiently, which can make it difficult to produce them as single crystals. The particle size of the primary particles may be, for example, 10 μm or less, 5 μm or less, or 3 μm or less. The particle size of the primary particles can be determined, for example, as the maximum diameter observed in TEM or SEM images. Alternatively, for example, when the cathode layer contains primary particles, the particle size of the primary particles may be determined from the maximum diameter of the primary particles in a cross-sectional SEM image of the cathode layer. The term “particle size of the primary particles” as used herein does not refer to an average particle size. That is, when multiple primary particles are contained in the cathode active material, the “particle size of the primary particles” refers to the particle size of each individual primary particle. The average particle size of the cathode active material particles may be, for example, 0.5 μm or more, or 1.0 μm or more. The average particle size of the cathode active material particles may be, for example, 100 μm or less, or 30 μm or less.

The primary particles constituting the cathode active material are stacked such that their (003) planes are oriented parallel to each other.

As used herein, the term “parallel” includes perfectly parallel orientations and orientations slightly tilted within ±5°, inclusive.
The primary particles constituting the cathode active material may not overlap each other in a direction parallel to the (003) planes. The primary particles not overlapping each other in the direction parallel to the (003) planes can reduce the diffusion distance of lithium ions within the cathode active material in the direction parallel to the (003) planes.
The cathode active material in which two or more primary particles are stacked with their (003) planes oriented parallel to each other may have a long axis and a short axis, and the short-axis direction of the cathode active material may be parallel to the (003) planes. When the short-axis direction of the cathode active material is parallel to the (003) planes, the diffusion distance of lithium ions within the cathode active material can be reduced compared with a case where the long-axis direction of the cathode active material is parallel to the (003) planes.

The ratio of the length of the shortest primary particle to the length of the longest primary particle among the primary particles, in the direction parallel to the (003) planes of the primary particles, is from 0.95 to 1. This ratio serves as an index indicating the degree of stacking misalignment of the primary particles included in the cathode active material, and the stacking misalignment of the primary particles may be in the range of 0% to 5%.

When the cathode active material is observed in cross section with a transmission electron microscope, the lengths of the primary particles in the direction parallel to the (003) planes may be equal. As used herein, the “length” of a primary particle may or may not be the particle diameter of the primary particle. When the length of a primary particle corresponds to the maximum diameter of the primary particle in a TEM or SEM image, the length represents the particle diameter of the primary particle. When adjacent primary particles have equal lengths in the direction parallel to their (003) planes, the (003) planes derived from the primary particles may be exposed at surfaces extending in the direction parallel to the (003) planes, while planes of the primary particles other than the (003) planes may be exposed at surfaces extending in the direction perpendicular to the (003) planes, as observed at the outer boundary of the cathode active material in cross section.
The planes of the primary particles other than the (003) planes may be (012) planes, (101) planes, (104) planes, or (110) planes.
Among these, at the outer boundary of the cathode active material observed in a cross-sectional TEM view, the (003) planes of the primary particles located at both ends in the stacking direction may be exposed at surfaces extending in the direction parallel to the (003) planes, while the (104) planes of the primary particles may be exposed at surfaces extending in the direction perpendicular to the (003) planes.

### 2. Method for Producing Cathode Active Material

The present disclosure provides a method for producing the above cathode active material. The method includes:
performing first firing in which a first mixture of a transition metal hydroxide and a lithium compound is fired at 700° C. to 1100° C. to obtain a precursor of the cathode active material; applying a magnetic field to a slurry in which the precursor of the cathode active material is dispersed in a solvent;
drying the slurry to obtain a dried product;
performing second firing in which the dried product is fired at 800° C. to 1000° C. to obtain a second-fired product; and
cooling the second-fired product at a cooling rate of 0.2° C./min to 0.5° C./min to obtain the cathode active material.

The method for producing the cathode active material according to the present disclosure includes: (1) a first firing step, (2) a magnetic-field application step, (3) a drying step, (4) a second firing step, and (5) a cooling step.

In the present disclosure, primary particles of the transition metal hydroxide are first synthesized. The primary particles are then subjected to the first firing to obtain a precursor of the cathode active material. Thereafter, a magnetic field is applied to a slurry containing the precursor, thereby orienting the precursor in the magnetic field such that the crystal orientations of the primary particles are aligned. The slurry is then dried, and the second firing allows the (003) planes of the primary particles to be joined to each another. Thereafter, the second-fired product is cooled at a predetermined rate. This can reduce the stacking misalignment of the primary particles.

### (1) First Firing Step

The first firing step is a step of firing a first mixture of a transition metal hydroxide and a lithium compound at 700° C. to 1100° C. to obtain a precursor of the cathode active material.

The method for producing the transition metal hydroxide used in the present disclosure is not particularly limited, and examples include the following. First, a raw material aqueous solution for the transition metal hydroxide is prepared. As an example of a method for preparing the raw material aqueous solution, a water-soluble transition metal compound may be dissolved in water. Examples of transition metal compounds include metal salts such as sulfates and nitrates. Examples of Ni sources include NiSO₄ and Ni(NO₃)₂. Examples of Co sources include CoSO₄, Co(NO₃)₂, and Co(NO₃)₃. Examples of Mn sources include MnSO₄ and Mn(NO₃)₂. The composition of the raw material aqueous solution is adjusted as appropriate in accordance with the target cathode active material.

Next, a predetermined amount of aqueous NH₃ solution is placed in a reaction vessel, and while stirring the solution with a stirrer etc., the atmosphere inside the reaction vessel is purged with nitrogen to create a non-oxidizing atmosphere. The flow rate of nitrogen gas for the nitrogen purging is not particularly limited, and may be, for example, from 2 L/min to 6 L/min.
Subsequently, an aqueous sodium hydroxide solution is added to the reaction vessel, and while maintaining the pH in the alkaline range (e.g., pH 11.3 to pH 12.0), the raw material aqueous solution and the aqueous NH₃ solution are added dropwise into the reaction vessel over one hour to seven hours. The reaction temperature is not particularly limited, and may be, for example, 50° C. or more and 65° C. or less.
After completion of the reaction, preliminary firing may be performed. The preliminary firing can be performed, for example, at 120° C. to 220° C. for four hours to 10 hours at 0.2 Mpa to 1.0 MPa.
After completion of the reaction or after completion of the preliminary firing, the resulting product is washed with water, and filtered to recover the transition metal hydroxide, and the recovered transition metal hydroxide is dried. The drying may be performed, for example, at 110° C. for 10 hours to 12 hours.

In the present disclosure, the transition metal hydroxide contains a transition metal. The transition metal hydroxide may be a nickel-cobalt-manganese composite hydroxide containing nickel (Ni), cobalt (Co), and manganese (Mn). In the nickel-cobalt-manganese composite hydroxide, the proportion (molar ratio) of each metal species to the total amount of nickel, cobalt, and manganese is the same as the composition ratio represented by the above general formula for the lithium transition metal composite oxide in the cathode active material.

The lithium compound (Li source) may be, for example, at least one selected from lithium carbonate, lithium nitrate, lithium acetate, lithium hydroxide, lithium oxide, and lithium chloride. The lithium compound may be lithium hydroxide. The molar ratio of Li in the Li source to the transition metal (TM) contained in the transition metal hydroxide may be, for example, 0.4 or more, 0.6 or more, 0.8 or more, 1.0 or more, or 1.1 or more, and may be 1.4 or less, or 1.2 or less.

The ratio of the lithium compound to the transition metal hydroxide in the first mixture is typically adjusted such that the proportion (molar ratio) of lithium and the other metal species to the total amount of lithium and the metal species contained in the transition metal hydroxide in the target cathode active material typically becomes equal to the proportion (molar ratio) of lithium and the other metal species in the first mixture. The mixing method is not particularly limited, and any known method may be used.
The first mixture may contain a molten salt. Since the molten salt functions as a flux, the primary particles can be sufficiently grown. The molten salt may contain Li. An example of the molten salt is lithium hydroxide. The molar ratio of Li contained in the molten salt to the transition metal (TM) in the transition metal hydroxide (Li/TM) may be, for example, 0.01 or more, or may be 0.05 or more, 0.10 or more, or 0.15 or more. The ratio Li/TM may be, for example, 0.60 or less, or may be 0.50 or less, 0.40 or less, or 0.30 or less.
The first mixture may contain lithium hydroxide as both the Li source and the molten salt. The molar ratio of Li contained in the Li source and molten salt to the transition metal (TM) in the transition metal hydroxide (Li′/TM) may be, for example, 1.01 or more, or may be 1.05 or more, 1.10 or more, or 1.15 or more. The ratio Li′/TM may be, for example, 1.60 or less, or may be 1.50 or less, 1.40 or less, or 1.30 or less.

The first mixture may be fired, for example, at 700° C. to 1100° C. for eight hours to 15 hours to obtain a lithium transition metal composite oxide. A known firing furnace such as a muffle furnace may be used for the firing.

The lower limit of the firing temperature in the first firing step may be 800° C. or more, 850° C. or more, 900° C. or more, or 950° C. or more, and the upper limit thereof may be 1000° C. or less.
The firing time in the first firing step may be nine hours or more, or 10 hours or more.
The firing time in the first firing step may be 13 hours or less, or 11 hours or less.
The precursor of the cathode active material obtained by firing the transition metal hydroxide in the present disclosure is typically a single-crystal active material formed of primary particles.

### (2) Magnetic-Field Application Step

The magnetic-field application step is a step of applying a magnetic field to a slurry in which the precursor of the cathode active material is dispersed in a solvent.

The solvent may be N-methyl-2-pyrrolidone (NMP) or the like.
The strength of the applied magnetic field may be 0.8 T to 2 T, or may be 1 T to 1.5 T.
The magnetic field may be applied for one minute to one hour, and or may be applied for five minutes to 10 minutes.

### (3) Drying Step

The drying step is a step of drying the slurry to obtain a dried product.

The drying temperature may be, for example, 90° C. to 110° C., or may be 100° C.
The drying time may be, for example, one minute to one hour, and may be five minutes to 10 minutes.

### (4) Second Firing Step

The second firing step is a step of firing the dried product at 800° C. to 1000° C. to obtain a second-fired product.

The lower limit of the firing temperature in the second firing step may be 850° C. or more, or 900° C. or more, and the upper limit thereof may be 950° C. or less.
The firing time in the second firing step may be one hour or more, nine hours or more, or 10 hours or more. The firing time in the second firing step may be 15 hours or less, 13 hours or less, or 11 hours or less.

### (5) Cooling Step

The cooling step is a step of cooling the second-fired product at a cooling rate of 0.2° C./min to 0.5° C./min to obtain the cathode active material.

The cooling rate may be any value within the range of 0.2° C./min to 0.5° C./min.

### 3. Battery

The cathode active material provided by the present disclosure can be used as, for example, a cathode active material constituting the cathode layer of a battery (such as a lithium-ion battery). That is, in the present disclosure, a battery is provided in which a cathode layer, an electrolyte layer, and an anode layer are stacked in this order, and the cathode layer contains the cathode active material of the present disclosure.

According to the present disclosure, the internal resistance of a battery can be reduced by using the above-described cathode active material.

The type of the battery in the present disclosure is not particularly limited, but is typically a lithium-ion battery. The battery in the present disclosure may be a liquid-electrolyte battery in which the electrolyte layer contains a liquid electrolyte, or a solid-state battery in which the electrolyte layer contains a solid electrolyte. The solid-state battery may be a semi-solid-state battery or an all-solid-state battery. In the present disclosure, a semi-solid-state battery is a battery in which the electrolyte layer contains solid components such as an inorganic solid electrolyte and liquid components (such as a solvent and a liquid electrolyte). In the present disclosure, an all-solid-state battery is a battery in which the electrolyte layer contains solid components such as an inorganic solid electrolyte as the electrolyte. The battery in the present disclosure may be a primary battery or a secondary battery, and may particularly be a secondary battery. This is because a secondary battery can be repeatedly charged and discharged and is therefore useful as, for example, an in-vehicle battery.

The shape of the battery is not particularly limited. For example, the battery may be a coin battery, a cylindrical battery, a prismatic battery, a sheet battery, a button battery, a flat battery, or a laminated battery.
In the case of a battery stack in which multiple cells are stacked, the battery stack may be monopolar or bipolar.

Examples of applications of the battery include power sources for vehicles such as hybrid electric vehicles (HEVs), plug-in hybrid electric vehicles (PHEVs), battery electric vehicles (BEVs), gasoline vehicles, and diesel vehicles. In particular, the battery may be used as a drive power source for hybrid electric vehicles (HEVs), plug-in hybrid electric vehicles (PHEV), or battery electric vehicles (BEVs). The battery may also be used as a power source for mobile bodies other than vehicles (for example, trains, ships, and aircraft), or as a power source for electric devices such as information processing devices.

The present disclosure is not limited to the above embodiment. The above embodiment is merely illustrative, and any structure that has substantially the same configuration as, and exhibits functions and effects similar to, the technical idea described in the claims of the present disclosure is included within the technical scope of the present disclosure.

### Example 1

### Synthesis of Transition Metal Hydroxides

NiSO₄, CoSO₄, and MnSO₄ were dissolved in deionized water to prepare a raw material aqueous solution. The molar ratio of Ni, Co, and Mn in the raw material aqueous solution was Ni:Co:Mn=80:10:10. The concentration of the raw material aqueous solution (the proportion of all raw materials in the raw material aqueous solution) was 30 mass %.

### Hydrothermal Synthesis (Crystallization)

A predetermined amount of aqueous NH₃ solution was placed in a reaction vessel, and while stirring the solution with a stirrer, the atmosphere inside the reaction vessel was purged with nitrogen. An aqueous NaOH solution was then added to the reaction vessel, and while maintaining the pH at an alkaline level (pH=12) and keeping the temperature constant, the raw material aqueous solution and the aqueous NH₃ solution were added dropwise to precipitate a transition metal hydroxide. The reaction temperature was 60° C., and the reaction time was 10 hours.

### Filtration

After completion of the hydrothermal synthesis, the transition metal hydroxide was dispersed and washed with deionized water. The washed transition metal hydroxide was then filtered to recover the transition metal hydroxide.

### Drying

The transition metal hydroxide was dried at 120° C. for 16 hours to remove moisture.

### Synthesis of Cathode Active Material

### Mixing of Li Raw Material

The dried transition metal hydroxide and LiOH, used as the lithium compound serving as the Li source, were mixed in an agate mortar to obtain a mixture.

The transition metal hydroxide and LiOH were mixed such that the molar ratio of the lithium compound to the total amount of Ni, Co, and Mn (NCM) contained in the transition metal hydroxide (Li/NCM ratio) became 1.1.

### First Firing

The resulting mixture was fired in a firing furnace at 1000° C. for 10 hours under an oxygen atmosphere to synthesize a cathode active material (Li_{1.1}Ni_{0.8}Co_{0.1}Mn_{0.1}O₂), thereby obtaining a first-fired product.

### First Pulverization

The first-fired product was pulverized with a jet mill as a pulverizer and further comminuted to a predetermined particle size.

### Magnetic Field Orientation

A beaker was charged with 100 mL of NMP and 50 g of the first-fired product, and the mixture was stirred to obtain a slurry. The resulting slurry was then allowed to stand for 10 minutes in a space where 1-T magnets were placed on the right and left sides.

### Slurry Drying

After the standing period, the beaker was gently transferred to a dryer, and the slurry was dried at 150° C. for six hours.

### Second Firing

The dried product thus obtained was gently transferred into an alumina crucible and fired in a firing furnace at 800° C. for 10 hours under an oxygen atmosphere to obtain a second-fired product of the cathode active material.

### Cooling

The second-fired product thus obtained was cooled at a cooling rate of 0.2° C./min under an oxygen atmosphere.

### Second Pulverization

The second-fired product was pulverized with a jet mill as a pulverizer and further comminuted to a predetermined particle size, thereby obtaining particles of the cathode active material.

### Example 2

Except that the cooling rate was set to 0.5° C./min in the above “Cooling,” the cathode active material was produced in the same manner as in Example 1.

### Comparative Example 1

Except that the steps from “Magnetic Field Orientation” to “Second Pulverization” were omitted, and the particles of the first-fired product obtained in “First Pulverization” of “Synthesis of Cathode Active Material” were used as the cathode active material, the cathode active material was produced in the same manner as in Example 1.

### Comparative Example 2

Except that the cooling rate was set to 2.0° C./min in the “Cooling,” the cathode active material was produced in the same manner as in Example 1.

### TEM Analysis

The cathode active materials of Examples 1 and 2 and Comparative Examples 1 and 2 were observed using TEM images.

At the outer boundaries of the cathode active materials of Examples 1 and 2 observed in the cross-sectional TEM images, the (003) planes of the primary particles located at both ends in the stacking direction were exposed, and the (104) planes of the primary particles were exposed at surfaces extending in the direction perpendicular to the (003) planes.
In a cross-sectional TEM view of the cathode active material, it was confirmed that, in the cathode active materials of Examples 1 and 2, the primary particles were stacked such that their (003) planes were oriented parallel to each other.
In a cross-sectional TEM view of the cathode active material, it was confirmed that, in the cathode active materials of Examples 1 and 2, the ratio of the length of the shortest primary particle to the length of the longest primary particle among the primary particles, in the direction parallel to the (003) planes, was in the range of0.95 to 1 (the stacking misalignment of the primary particles was 5% or less).
In a cross-sectional TEM view of the cathode active material, it was also confirmed that the primary particles of the cathode active materials of Examples 1 and 2 did not overlap each other in the direction parallel to their (003) planes, and that the short-axis direction of the cathode active materials of Examples 1 and 2 was parallel to the (003) planes of the primary particles.
In a cross-sectional TEM view of the cathode active material, it was further confirmed that, in the cathode active materials of Comparative Examples 1 and 2, the ratio of the length of the shortest primary particle to the length of the longest primary particle among the primary particles, in the direction parallel to the (003) planes, was less than 0.95 (the stacking misalignment of the primary particles exceeded 5%).

### Cell Fabrication (Wound Cylindrical Cells)

Wound cylindrical cells of Examples 1 and 2 and Comparative Examples 1 and 2 were fabricated using the cathode active materials of Examples 1 and 2 and Comparative Examples 1 and 2, respectively.

Specifically, a cathode mixture paste containing the cathode active material, acetylene black as a conductive additive, and polyvinylidene fluoride as a binder was applied onto the surface of a metal foil serving as a cathode current collector using a film applicator with a thickness adjustment function (manufactured by Allgood Co., Ltd.). The coated metal foil was then dried at 80° C. for five minutes in a dryer to prepare a cathode having a cathode layer on the cathode current collector. The cathode mixture paste had a mass ratio of 88:10:2 (cathode active material:conductive additive:binder).
An anode mixture paste containing natural graphite as an anode active material, styrene-butadiene rubber (SBR) as a binder, and carboxymethyl cellulose (CMC) as a thickener was applied onto the surface of a metal foil serving as an anode current collector using a film applicator with a thickness adjustment function (manufactured by Allgood Co., Ltd.). The coated metal foil was then dried at 80° C. for five minutes in a dryer to produce an anode having an anode layer on the anode current collector.
A 1 M LiPF₆ solution containing LiPF₆ as an electrolyte and ethylene carbonate (EC), dimethyl carbonate (DMC), and ethyl methyl carbonate (EMC) as a solvent in a volume ratio of EC/DMC/EMC=3/4/3 was prepared as an electrolyte solution.
The cathode, a separator, and the anode were stacked, and the separator was impregnated with the electrolyte solution. Wound cylindrical cells of Examples 1 and 2 and Comparative Examples 1 and 2 were thus fabricated.

### Cell Evaluation

The initial capacity and the I-V resistance were measured for each of the fabricated wound cylindrical cells.

### Measurement of Initial Capacity

The capacity was measured when the cell was charged at 0.3C at 50° C. within a voltage range of 3.0 V to 4.3 V. The results are shown in Table 1. The initial capacities of Examples 1 and 2 and Comparative Examples 1 and 2 shown in Table 1 are relative values, with the initial capacity of Comparative Example 1 defined as 100%.

### Measurement of I-V Resistance

In the voltage range of 3.0 V to 4.3 V, the upper limit voltage of 4.3 V was defined as a state of charge (SOC) of 100%, and the voltage was adjusted such that the SOC became 50%.

Discharge was performed at 0° C. for 10 seconds at 0.1C, 0.3C, 0.5C, 0.7C, and 1.0C, and the voltage drop (V) observed during the discharge was measured.
The relationship between current and voltage drop (V) was plotted, and the slope of the straight line obtained by linear approximation was defined as the I-V resistance. The results are shown in Table 1. The resistance values of Examples 1 and 2 and Comparative Examples 1 and 2 shown in Table 1 are relative values, with the resistance value of Comparative Example 1 defined as 100%.

TABLE 1

| | | | | | | | Primary | Initial | Initial |
|---|---|---|---|---|---|---|---|---|---|
| | | | | | | | Particles | Capacity | Resistance |
| | | | | | Magnetic | | Presence/ | Relative | Relative |
| | | | | | Field | Cooling | Absence | Value (%) | Value (%) |
| | Cathode Active Material | | | | Orientation | Cooling | of >5% | (Comparative | (Comparative |
| | Li/NCM | Ni/NCM | Co/NCM | Mn/NCM | Presence/ | Rate | Stacking | Example | Example |
| | Ratio | Ratio | Ratio | Ratio | Absence | (° C./min) | Misalignment | 1 = 100%) | 1 = 100%) |
| Comparative | 1.1 | 0.8 | 0.1 | 0.1 | Absent | — | Present | 100 | 100 |
| Example 1 | | | | | | | | | |
| Comparative | 1.1 | 0.8 | 0.1 | 0.1 | Present | 2.0 | Present | 101 | 99 |
| Example 2 | | | | | | | | | |
| Example 1 | 1.1 | 0.8 | 0.1 | 0.1 | Present | 0.2 | Absent | 110 | 85 |
| Example 2 | 1.1 | 0.8 | 0.1 | 0.1 | Present | 0.5 | Absent | 109 | 87 |

As shown in Table 1, the batteries using the cathode active materials of Examples 1 and 2 exhibit larger initial capacity and lower I-V resistance than the batteries using the cathode active materials of Comparative Examples 1 and 2. Accordingly, by using a cathode active material in which the primary particles are stacked such that their (003) planes are oriented parallel to each other in a cross-sectional TEM image, and in which the ratio of the length of the shortest primary particle to the length of the longest primary particle among the primary particles, in the direction parallel to the (003) planes, is from 0.95 to 1, it is possible to increase the initial capacity and reduce the I-V resistance of the battery.

What is claimed is:

1. A cathode active material comprising at least one element selected from the group consisting of Ni, Co, and Mn, wherein:
the cathode active material has a form in which two or more primary particles overlap each other;
the primary particles are single crystals having a crystal structure belonging to space group R-3m;
the primary particles are stacked such that (003) planes of the primary particles are oriented parallel to each other; and
a ratio of a length of a shortest primary particle to a length of a longest primary particle among the primary particles, in a direction parallel to the (003) planes of the primary particles, is from 0.95 to 1.

2. The cathode active material according to claim 1, wherein:
the cathode active material has a form in which two to ten of the primary particles overlap each other;
the primary particles do not overlap each other in the direction parallel to the (003) planes of the primary particles; and
a short-axis direction of the cathode active material is parallel to the (003) planes of the primary particles.

3. The cathode active material according to claim 1, wherein:
in an outer boundary of the cathode active material observed in a cross-sectional view obtained by a transmission electron microscope, the (003) planes derived from the primary particles are exposed at surfaces extending in the direction parallel to the (003) planes of the primary particles, and planes of the primary particles other than the (003) planes are exposed at surfaces extending in a direction perpendicular to the (003) planes of the primary particles; and
the planes of the primary particles other than the (003) planes are (012) planes, (101) planes, (104) planes, or (110) planes.

4. A battery comprising a cathode layer containing the cathode active material according to claim 1.

5. A method for producing the cathode active material according to claim 1, the method comprising:
performing first firing in which a first mixture of a transition metal hydroxide and a lithium compound is fired at 700° C. to 1100° C. to obtain a precursor of the cathode active material;
applying a magnetic field to a slurry in which the precursor of the cathode active material is dispersed in a solvent;
drying the slurry to obtain a dried product;
performing second firing in which the dried product is fired at 800° C. to 1000° C. to obtain a second-fired product; and
cooling the second-fired product at a cooling rate of 0.2° C./min to 0.5° C./min to obtain the cathode active material.
